(19) United States
(12) Patent Application Publication
(10) Pub. No.: US 2019/0287963 A1
(43) Pub. Date: Sep. 19, 2019

(54) SEMICONDUCTOR DEVICE

(71) Applicant: TOYOTA JIDOSHA KABUSHIKI KAISHA, Toyota-shi (JP)

(72) Inventors: Keiichi KONDOH, Nagoya-shi (JP); Masaru SENOO, Okazaki-shi (JP); Hiroshi HOSOKAWA, Nagoya-shi (JP)

(73) Assignee: TOYOTA JIDOSHA KABUSHIKI KAISHA, Toyota-shi (JP)

(21) Appl. No.: 16/279,273

(22) Filed: Feb. 19, 2019

(30) Foreign Application Priority Data
Mar. 15, 2018 (JP) 2018-048303

(51) Int. Cl. H01L 27/07; H01L 29/739; H01L 29/417; H01L 29/08; H01L 29/10

(52) U.S. Cl. CPC H01L 27/0716; H01L 29/7397; H01L 29/1095; H01L 29/083; H01L 29/41708

(57) ABSTRACT

A semiconductor device may include a semiconductor substrate, a plurality of trenches, an insulating film, a control electrode, an upper electrode, and a lower electrode. A diode region of the semiconductor substrate may include an n-type bypass region being in direct contact with each insulating film and connected to the upper electrode, a p-type anode contact region connected to the upper electrode, a p-type body region disposed below the bypass region and the anode contact region and being in direct contact with each insulating film below the bypass region, an n-type drift region being in direct contact with each insulating film below the body region, and an n-type cathode region disposed below the drift region and connected to the lower electrode. A position of a lower end of the anode contact region may be located below a position of a lower end of the bypass region.

### CROSS-REFERENCE TO RELATED APPLICATION

This application claims priority to Japanese Patent Application No. 2018-048303, filed on Mar. 15, 2018, the entire contents of which are incorporated herein by reference.

### TECHNICAL FIELD

The disclosure herein relates to a semiconductor device.

### BACKGROUND

Japanese Patent Application Publication No. 2014-170780 describes a semiconductor device that includes a semiconductor substrate including an IGBT region and a diode region. This semiconductor device includes a plurality of trenches provided in an upper surface of the semiconductor substrate in the IGBT region and the diode region, an insulating film covering an inner surface of each of the trenches, a control electrode disposed in each of the trenches and insulated from the semiconductor substrate by its corresponding insulating film, an upper electrode provided on the upper surface of the semiconductor substrate, and a lower electrode provided on a lower surface of the semiconductor substrate, In this semiconductor device, the diode region includes a bypass region, an anode contact region, a body region, a drift region, and a cathode region. The bypass region is an n-type region disposed at the upper surface of the semiconductor substrate, being in direct contact with each insulating film, and connected to the upper electrode. The anode contact region is a p-type region disposed at the upper surface of the semiconductor substrate and connected to the upper electrode. The body region is a p-type region disposed below the bypass region and the anode contact region, being in direct contact with each insulating film below the bypass region, and having a p-type impurity concentration lower than that of the anode contact region. The drift region is an n-type region being in direct contact with each insulating film below the body region. The cathode region is an n-type region disposed below the drift region, disposed at the lower surface of the semiconductor substrate, having an n-type impurity concentration higher than that of the drift region, and connected to the lower electrode.

In the semiconductor device in Japanese Patent Application Publication No. 2014-170780, when a forward voltage applied to the diode is raised, electrons flow from the cathode region toward the upper electrode. The electrons flow to the upper electrode mainly through the bypass region, so that holes are suppressed flowing from the anode contact region into the drift region. When the voltage applied to the diode is switched from a forward voltage to a reverse voltage, the diode starts a recovery operation. In other words, holes in the drift region are ejected to the upper electrode, and a recovery current flows in the diode. Since holes flow into the drift region at a smaller quantity during the application of the forward voltage to the diode, the recovery current is small in this semiconductor device. Loss is thus less likely to occur during the recovery operation in this semiconductor device.

### SUMMARY

In the semiconductor device in Japanese Patent Application Publication No. 2014-170780, When the diode is turned on, the electrons flow from the body region to the upper electrode through the bypass region. The electrons are more likely to flow to the upper electrode through the bypass region, and hence when the forward voltage applied to the diode is raised, an increase in a forward current may be temporarily delayed with respect to the rise in the forward voltage, namely, a snapback phenomenon may occur, Occurrence of such a snapback phenomenon increases the loss in the diode. The present specification provides a technology capable of suppressing a snapback phenomenon while reducing recovery loss.

A semiconductor device disclosed herein may comprise a semiconductor substrate including an IGBT (Insulated Gate Bipolar Transistor) region and a diode region. The semiconductor device may comprise: a plurality of trenches provided in an upper surface of the semiconductor substrate in the IGBT region and the diode region; an insulating film covering an inner surface of each of the trenches; a control electrode disposed in each of the trenches and insulated from the semiconductor substrate by its corresponding insulating film; an upper electrode provided on the upper surface of the semiconductor substrate; and a lower electrode provided on a lower surface of the semiconductor substrate. The diode region may comprise; a bypass region; an. anode contact region; a body region; a drift region; and a cathode region. The bypass region may be an n-type region which is disposed at the upper surface of the semiconductor substrate, in direct contact with each insulating film, and connected to the upper electrode. The anode contact region may be a p-type region which is disposed at the upper surface of the semiconductor substrate and connected to the upper electrode. The body region may be a p-type region which is disposed below the bypass region and the anode contact region, in direct contact with each insulating film below the bypass region, and has a p-type impurity concentration lower than the anode contact region. The drift region may be an n-type region which is in direct contact with each insulating film below the body region. The cathode region may be an n-type region which is disposed below the drift region, disposed at the lower surface of the semiconductor substrate, has an n-type impurity concentration higher than the drift region, and connected to the lower electrode. A position of a lower end of the anode contact region may be located below a position of a lower end of the bypass region.

In the above semiconductor device, the position of the lower end of the anode contact region is located below the position of the lower end of the bypass region. Therefore, a part of electrons that flow from the cathode region toward the upper electrode along a side surface of each of the trenches are more likely to be ejected to the upper electrode via the anode contact region. Electrons that flow to the upper electrode through the bypass region are thus decreased, and a snapback phenomenon can be suppressed.

### BRIEF DESCRIPTION OF DRAWINGS

FIG. 1 is a vertical cross-sectional view of a semiconductor device 10 in a first embodiment.

FIG. 2 is a vertical cross-sectional view of a semiconductor device 210 in a second embodiment.

FIG. 3 is a vertical cross-sectional view of a semiconductor device 310 in a third embodiment.

FIG. 4 is a vertical cross-sectional view of a semiconductor device in a variant.

### DETAILED DESCRIPTION

Representative, non-limiting examples of the present invention will now be. described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved semiconductor devices, as well as methods for using and manufacturing the same.

Moreover, combinations of features and steps disclosed in the following detailed description may not be necessary to practice the invention in the broadest sense, and are instead tauglht merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter,

### First Embodiment

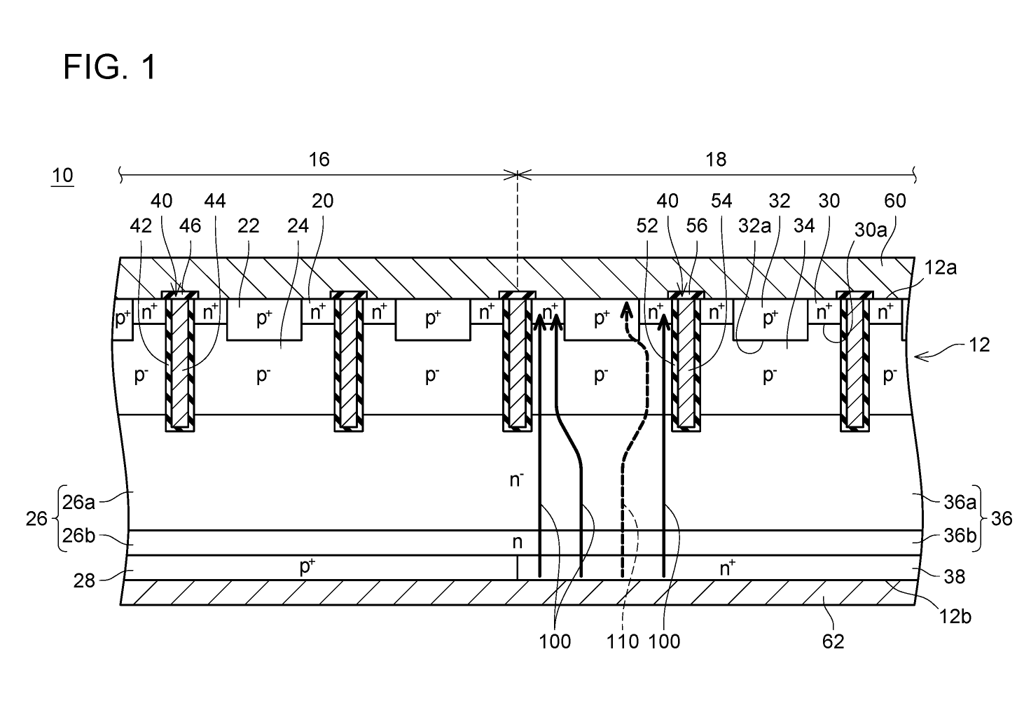

A semiconductor device 10 in a first embodiment shown in FIG. 1 is configured with a semiconductor substrate 12, electrodes disposed on an upper surface 12a and a lower surface 12b of the semiconductor substrate 12, insulators, and the like. The semiconductor substrate 12 includes an IGBT (Insulated Gate Bipolar Transistor) region 16 including an IGBT, and a diode region 18 including a diode. in other words, the semiconductor device 10 is a so-called RC-IGBT (Reverse Conducting-IGBT).

The semiconductor substrate 12 is constituted of Si (silicon), for example. The upper surface 12a of the semiconductor substrate 12 is provided with a plurality of trenches 40 therein, The trenches 40 extend in parallel to one another along a direction perpendicular to a sheet surface of FIG. 1.

An inner surface of each of the trenches 40 in the IGBT region 16 is covered with a gate insulating film 42. Disposed in each of the trenches 40 in the IGBT region 16 is a gate electrode 44. Each of the gate electrodes 44 is insulated from the semiconductor substrate 12 by its corresponding gate insulating film 42. A surface of each gate electrode 44 is covered with an interlayer insulating film 46.

An inner surface of each of the trenches 40 in the diode region 18 is covered with an insulating film 52. Disposed in each of the trenches 40 in the diode region 18 is a control electrode 54. Each of the control electrodes 54 is insulated from the semiconductor substrate 12 by its corresponding insulating film 52. A surface of each control electrode 54 is covered with an interlayer insulating film. 56. A potential of th.e control electrodes 54 is controlled independently of a potential of the gate electrodes 44.

An upper electrode 60 is disposed on the upper surface 12a of the semiconductor substrate 12. The upper electrode 60 is insulated from the gate electrodes 44 by their corresponding interlayer insulating films 46, and is insulated from the control electrodes 54 by their corresponding interlayer insulating films 56. A lower electrode 62 is disposed on the lower surface 12b of the semiconductor substrate 12.

The IGBT region 16 includes emitter regions 20, body contact regions 22, a body region 24, a drift region 26, and a collector region 28.

The emitter regions 20 are n-type regions, and are disposed at the upper surface 12a of the semiconductor substrate 12. The emitter regions 20 are in ohmic contact with the upper electrode 60, The emitter regions 20 are in direct contact with their corresponding gate insulating films 42.

The body contact regions 22 are p-type region that contain a high concentration of p-type impurities. The body contact regions 22 are disposed at the upper surface 12a of the semiconductor substrate 12. The body contact regions 22 are in ohmic contact with the upper electrode 60. Each of the body contact regions 22 is adjacent to its corresponding emitter regions 20.

The body region 24 is a p-type region having a p-type impurity concentration lower than a p-type impurity concentration of the body contact regions 22. The body region 24 is disposed below the emitter regions 20 and the body contact regions 22. The body region 24 is in direct contact with each of the gate insulating films 42 below the emitter regions 20.

The drift region 26 includes a :low-concentration. drift region 26a and a buffer region 26b.

The low-concentration drift region 26a is an n-type region having an n-type impurity concentration lower than n-type impurity concentrations of the emitter regions 20 and the buffer region 26b. The low-concentration drift region 26a is disposed below the body region 24. The low-concentration drift region 26a is separated from the emitter regions 20 by the body region 24. The low-concentration drift region 26a is in direct contact with the gate insulating films 42 in a vicinity of lower end portions of the trenches 40, below the body region 24.

The buffer region 26b is an n-type region having the n-type impurity concentration higher than that of the low-concentration drift region 26a. The buffer region 26h is disposed below the low-concentration drift region 26a.

The collector region 28 is a p-type region that contains a high concentration of p-type impurities. The collector region 28 is disposed below the buffer region 26b. The collector region 28 is separated from the body region 24 by the drift region 26, The collector region 28 is disposed at the lower surface 12b of the semiconductor substrate 12. The collector region 28 is in ohmic contact with the lower electrode 62,

The IGBT region 16 includes the IGBT configured with the emitter regions 20, the body contact regions 22, the body region 24, the drift region 26, the collector region 28, the gate electrodes 44, and the like, and is connected between the upper electrode 60 and the lower electrode 62. When the semiconductor device 10 operates as the IGBT, the upper electrode 60 is an emitter electrode, and the lower electrode 62 is a collector electrode.

The diode region 18 includes bypass regions 30, anode contact regions 32, a body region 34, a drift region 36, and a cathode region 38.

The bypass regions 30 are n-type regions, and are disposed at the upper surface 12a of the semiconductor substrate 12, The bypass regions 30 are in ohmic contact with the upper electrode 60. The bypass regions 30 are in direct contact with their corresponding insulating film 52.

The anode contact regions 32 are p-type regions that contain a high concentration of p-type impurities. The anode contact regions 32 axe disposed at the upper surface 12a of the semiconductor substrate 12. The anode contact regions 32 are in ohmic contact with the upper electrode 60. Each of the anode contact regions 32 is adjacent to its corresponding bypass regions 30. Positions of lower ends 32a of the anode contact regions 32 are located below positions of lower ends 30a of the bypass regions 30.

The body region 34 is a p-type region having a p-type impurity concentration lower than a p-type impurity concentration of the anode contact regions 32. The body region 34 is disposed below the bypass regions 30 and the anode contact regions 32. The body region 34 is in direct contact with each of the insulating films 52 below the bypass regions 30.

The drift region 36 is an n-type region provided continuously adjacent to the drift region 26. The drift region 36 includes a low-concentration. drift region 36a and a buffer region 36b.

The low-concentration drift region 36a is an n-type region having an n-type impurity concentration lower than an n-type impurity concentration of the bypass regions 30. The low-concentration drift region 36a is disposed below the body region 34. The low-concentration drift region 36a is separated from the bypass regions 30 by the body region 34. The low-concentration drift region 36a is in direct contact with the insulating films 52 in a vicinity of lower end portions of the trenches 40, below the body region 34. The low-concentration drift region 36a has the n-type impurity concentration approximately equal to that of the low-concentration drift region 26a in the IGBT region 16. The low-concentration drift region 36a is provided continuously adjacent to the low-concentration drift region 26a in the IGBT region 16.

The buffer region 36b is disposed below the low-concentration drift region 36a. The buffer region 36b is an n-type region having an n-type impurity concentration higher than that of the low-concentration drift region 36a. The buffer region 36b has the n-type impurity concentration approximately equal to that of the buffer region 26b in the IGBT region 16. The buffer region 36b is provided continuously adjacent to the buffer region 26b in the IGBT region 16.

The cathode region 38 is an n-type region having an n-type impurity concentration higher than that of the buffer region 36b. The cathode region 30 is disposed below the buffer region 36b. The cathode region 38 is disposed at the lower surface 12b of the semiconductor substrate 12. The cathode region 38 is in ohmic contact with the lower electrode 62. The cathode region 38 is adjacent to the collector region 28 in the IGBT region 16.

The diode region 18 includes the diode configured with the anode contact regions 32, the body region 34, the drift region 36, the cathode region 38, and the like, and connected between the upper electrode 60 and the lower electrode 62. When the semiconductor device 10 operates as the diode, the upper electrode 60 is an anode electrode, and the lower electrode 62 is a cathode electrode. In other words, the diode is connected in reverse parallel to the IGBT.

Next, an operation of the IGBT in the IGBT region 16 will be described. When a potential (i.e., a gate-emitter voltage) equal to or above a threshold value is applied to the gate electrodes 44, a channel is formed in a range of the body region 24 adjacent to each gate insulating film 42. When the channels are formed in a state where a potential that causes the lower electrode 62 to have a higher potential than the upper electrode 60 is applied, electrons flow from the upper electrode 60 to the lower electrode 62 through the emitter regions 20, the channels in the body region 24, the drift region 26, and the collector region 28, Moreover, holes flow from the lower electrode 62 to the upper electrode 60 through. the collector region 28, the drift region 26, the body region 24, and the body contact regions 22. In other words, the IGBT is turned on.

Subsequently, when the potential of the gate electrode 44 is decreased, the channels disappear. The holes that exist in the drift region 26 when the IGBT is on are then ejected to the upper electrode 60 through the body contact regions 22. The IGBT is thereby turned off.

Next, an operation of the diode in the diode region 18 will be described. When a forward voltage applied to the diode (i.e., a voltage that causes the upper electrode 60 to be positive relative to the lower electrode 62) is gradually raised, a pn junction between the body region 34 and the drift region 36 is turned on, and electrons flow from the cathode region 38 toward the upper electrode 60. The control electrode 54 has a low potential approximately equal to that of the upper electrode 60, so the electrons are attracted to a side surface of each of the trenches 40. This causes a large quantity of the electrons to move toward the upper electrode 60 along the side suffice of each of the trenches 40. As shown by solid arrows 100 in FIG. 1, the electrons then flow to the upper electrode 60 mainly through the bypass regions 30. In other words, the electrons flow from the cathode region 38 to the upper electrode 60 through the drift region 36, the body region 34, and the bypass regions 30. This suppresses flow of holes from the anode contact region 32 into the drift region 36. When the voltage applied to the diode is switched from the forward voltage to a reverse voltage, the diode starts a recovery operation. In other words, the holes in the drift region 36 are ejected to the upper electrode 60, and a recovery current flows in the diode. In this semiconductor device 10, holes flow into the drift region 36 in a smaller quantity during the application of the forward voltage to the diode, so that this small quantity of the holes is ejected from the drift region 36 to the upper electrode 60 during the recovery operation accordingly. hi other words, the recovery current is small in this semiconductor device 10. Loss is thus less likely to occur during the recovery operation in this semiconductor device 10.

It should be noted that, as shown by the arrows 100, an excessive flow of electrons to the bypass regions 30 causes a snapback phenomenon at turn-on of the diode. On the other hand, in the semiconductor device 10, the positions of the lower ends 32a of the anode contact regions 32 are located below the positions of the lower ends 30a of the bypass regions 30, so that occurrence of the snapback phenomenon is suppressed, In other words, if the lower ends 32a of the anode contact regions 32 are located below the lower ends 30a of the bypass regions 30, a part of the electrons that flow from the cathode region 38 toward the upper electrode 60 is more likely to be ejected to the upper electrode 60 through the anode contact region 32, as shown by a dashed arrow 110 in FIG. 1. Therefore, the electrons that flow to the upper electrode 60 through the bypass regions 30 decrease, The snapback phenomenon can thereby be suppressed in this semiconductor device 10 at the turn-on of the diode.

### Second Embodiment

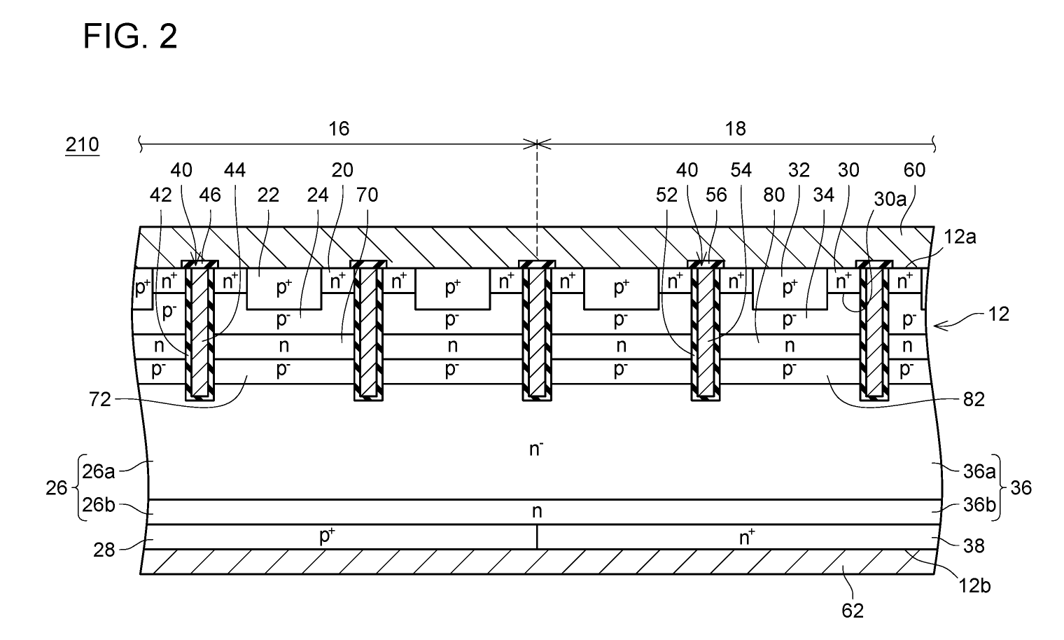

Next, with reference to FIG. 2, a semiconductor device 210 in a second embodiment will be described. Notably, a configuration in the semiconductor device 210 in the second embodiment similar to that in the first embodiment will be given a reference sign similar to that in the first embodiment, and description thereof will be omitted.

The semiconductor device 210 in the second embodiment includes an IGBT barrier region 70 and a lower body region 72 that are provided in the IGBT region 16, and a diode barrier region 80 and a lower body region 82 that are provided in the diode region 18.

The IGBT barrier region 70 is an n-type region having an n-type impurity concentration higher than that of the low-concentration drift region 26a, and is disposed below the body region 24. A pn junction is located at a boundary between the body region 24 and the IGBT barrier region 70. The IGBT barrier region 70 is separated from the emitter regions 20 by the body region 24. The IGBT barrier region 70 is in direct contact with each gate insulating film 42 below the body region 24.

The lower body region 72 is a p-type region, and is disposed below the IGBT barrier region 70 and above the low-concentration drift region 26a. The lower body region 72 is separated from the body region 24 by the IGBT barrier region 70. The lower body region 72 is in direct contact with each gate insulating film 42 below the IGBT barrier region 70.

The diode barrier region 80 is an n-type region having an n-type impurity concentration higher than that of the low-concentration drift region 36a, and is disposed below the body region 34. A pn junction is located at a boundary between the body region 34 and the diode barrier region 80. The diode barrier region 80 is separated from the bypass regions 30 by the body region 34. The diode barrier region 80 is in direct contact with each insulating film 52 below the body region 34.

The lower body region 82 is a p-type region, and is disposed below the diode barrier region 80 and above the low-concentration drift region 36a. The lower body region 82 is separated from the body region 34 by the diode barrier region 80. The lower body region 82 is in direct contact with each insulating film 52 below the diode barrier region 80.

In the semiconductor device 210 in the present embodiment, the diode barrier region 80 forms, in the diode region 18, a barrier against holes flowing from the anode contact region 32.

Therefore, provision of the diode barrier region 80 suppresses the holes flowing from the anode contact region 32 into the drift region 36 during the application of a forward voltage, and recovery loss is further reduced.

Moreover, the IGBT barrier region 70 forms, in the IGBT region 16, a barrier against holes flowing from the collector region 28. Therefore, the holes are less likely to flow from the lower body region 72 toward the body region 24 at turn-on of the IGBT. This causes the holes to be accumulated in the drift region 26, and decreases electrical resistance of the drift region 26. Loss that occurs in the IGBT is thereby reduced.

The diode barrier region 80 is an example of a barrier region.

### Third Embodiment

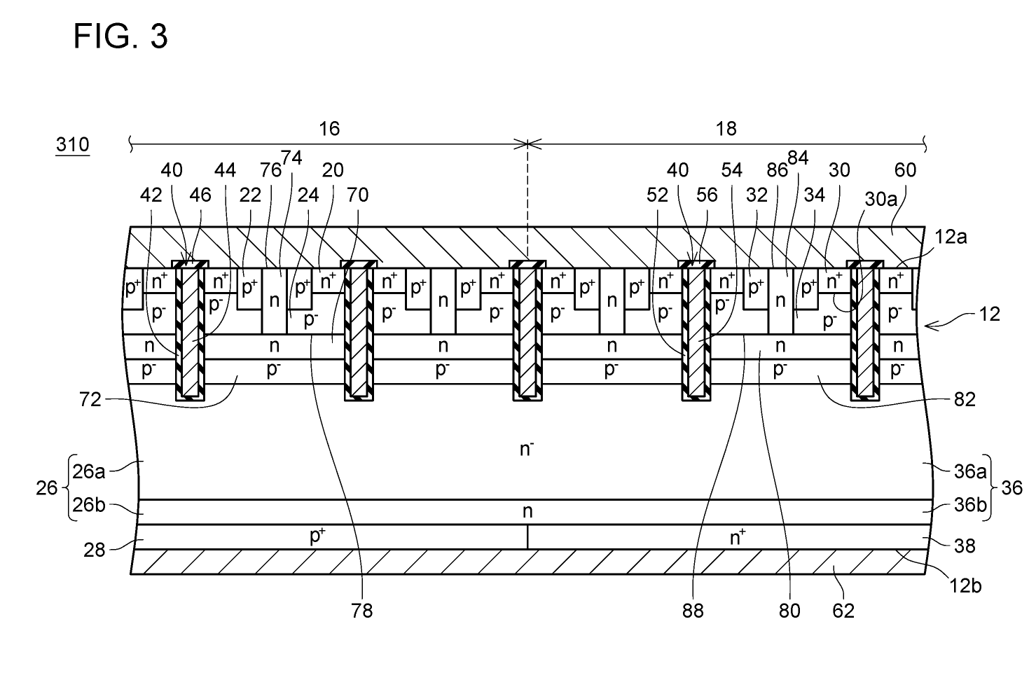

Next, with reference to FIG. 3, a semiconductor device 310 in a third embodiment will be described. The semiconductor device 310 in the third embodiment includes IGBT pillar regions 74 provided in the IGBT region 16, and diode pillar regions 84 provided in the diode region 18, in addition to the configuration of the semiconductor device 210 in the second embodiment.

The IGBT pillar regions 74 are n-type regions, and are each disposed in a region interposed between the trenches 40 in the IGBT region 16. The IGBT pillar regions 74 extend long from the upper surface 12a of the semiconductor substrate 12 in a thickness direction of the semiconductor substrate 12. The IGBT pillar regions 74 extend from the upper surface 12a of the semiconductor substrate 12 to the IGBT barrier region 70 through the body contact regions 22 and the body region 24. Lower ends of the IGBT pillar regions 74 are connected to the IGBT barrier region 70. Upper ends of the IGBT pillar regions 74 are in Schottky contact with the upper electrode 60, In other words, a Schottky junction 76 is disposed between each IGBT pillar region 74 and the upper electrode 60.

The diode pillar regions 84 are n-type regions, and are each disposed in a region interposed between the trenches 40 in the diode region 18. The diode pillar regions 84 extend long from the upper surface 12a of the semiconductor substrate 12 in the thickness direction of the semiconductor substrate 12. The diode pillar regions 84 extend from the upper surface 12a of the semiconductor substrate 12 to the diode barrier region 80 through the anode contact regions 32 and the body region 34. Lower ends of the diode pillar regions 84 are connected to the diode barrier region 80. Upper ends of the diode pillar regions 84 are in Schottky contact with the upper electrode 60. In other words, a Schottky junction 86 is disposed between each diode pillar region 84 and the upper electrode 60.

In the semiconductor device 310 in the present embodiment, when a forward voltage applied to the diode is raised, the Schottky junction 86 between the upper electrode 60 and each diode pillar region 84 is turned on, Electrons then flow from the lower electrode 62 toward the upper electrode 60 through the cathode region 38, the drift region 36, the lower body region 82, the diode barrier region 80, and the diode pillar regions 84. When the Schottky junctions 86 are turned on, a potential of the diode barrier region 80 approaches a potential of the upper electrode 60. A potential difference is thus less likely to occur at a. pn junction 88 at the boundary between the body region 34 and the diode barrier region 80. Therefore, even when the potential of the upper electrode 60 is subsequently raised, the pn junction 88 is not turned on for a while. When the potential of the upper electrode 60 is further raised, a current that flows via the Schottky junctions 86 increases. This increases the potential difference between the upper electrode 60 and the diode barrier region 80, and also increases the potential difference that occurs at the pn junction 88. Therefore, when the potential of the upper electrode 60 is raised to a potential equal to or above a predetermined potential, the pn junction $8 (i.e., the diode) is turned on, In other words, the electrons flow from the lower electrode 62 toward the upper electrode 60 in a path through the diode barrier region $0 and the body region 34.

As such, in the semiconductor device 310 in the present embodiment, when the potential of the upper electrode 60 rises, the Schottky junctions 86 are initially turned on, so that the timing at which the pn junction 88 is turned on is delayed. This suppresses an inflow of holes to the drift region 36. A recovery current is thereby less likely to flow during a recovery operation of the diode. Loss is thus less likely to occur during the recovery operation in the semiconductor device 310,

Notably, the semiconductor device 310 also has a parasitic diode provided in the IGBT region 16 and configured by a pn junction 78 between the body region 24 and the IGBT barrier region 70. Moreover, the IGBT barrier region 70 below the pn junction 78 is connected to the upper electrode 60 by the IGBT pillar regions 74, Therefore, as mentioned above, when the forward voltage (i.e., the potential of the upper electrode 60) rises, the current initially flows in the IGBT pillar regions 74. Subsequently, when the forward voltage further rises, the pn junction 78 that configures the parasitic diode is turned on, As such, also in the IGBT region 16, the timing at which the pn junction 78 is turned on is delayed, and the inflow of holes to the drift regions 26, 36 is suppressed. This also suppresses the recovery current.

Notably, the IGBT pillar regions 74 may not be provided in the IGBT region 16. In other words, the pillar regions may be provided only in the diode region 18.

The diode pillar region 84 of the embodiment is an example of “pillar region” in the claims.

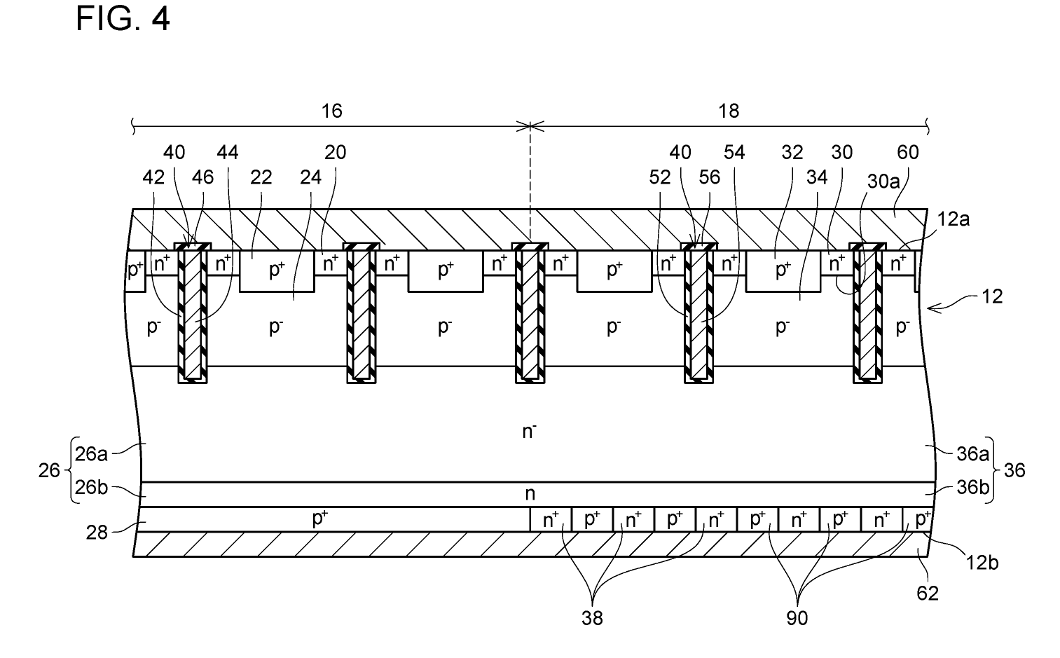

In the first embodiment mentioned above, the cathode region 38 is provided over almost an entire range of the diode region 18. In other words, in the diode region 18, the cathode region 38 is disposed over almost an entire range of the lower surface 12b of the semiconductor substrate 12. As shown in FIG. 4, however, the cathode region 38 may be divided into a plurality of portions by p-type interposing regions 90. In such a configuration, electrons are suppressed flowing from the lower surface 12.b of the semiconductor substrate 12, and recovery loss can further be reduced. Notably, the interposing regions 90 may also be used in other embodiments,

Some of the features characteristic to the technology disclosed herein will be listed below. It should be noted that the respective technical elements are independent of one another, and are useful solely or in combinations.

In a configuration disclosed herein as an example, the diode region may further comprise: an n-type barrier region disposed between the body region and the drift region, being in direct contact with each insulating film below the body region, and having an n-type impurity concentration higher than the drift region; and a p-type lower body region disposed between the barrier region and the drift region, being in direct contact with each insulating film below the barrier region, and separating the barrier region and the drift region.

In such a configuration, the barrier region. forms a potential barrier against holes flowing from the anode contact region. Therefore, when the forward voltage is applied to the diode region, the holes flowing from the anode contact region are suppressed, and the recovery loss can further be reduced.

In a configuration disclosed herein as an example, the diode region may further comprise an n-type pillar region extending from the upper surface of the semiconductor substrate to the barrier region through the anode contact region and the body region.

In such a configuration, when a forward voltage applied to the diode region rises, the timing at which the pn junction at the boundary between the body region and the barrier region is turned on is delayed, This suppresses the inflow of holes to the drift region. The recovery current is thus less likely to flow during the recovery operation of the diode. Therefore, the recovery loss can further be reduced.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A semiconductor device which comprises a semiconductor substrate including an IGBT (Insulated Gate Bipolar Transistor) region and a diode region, the semiconductor device comprising:
a plurality of trenches provided in an upper surface of the semiconductor substrate in the IGBT region and the diode region;
an insulating film covering an inner surface of each of the trenches;
a control electrode disposed in each of the trenches and insulated from the semiconductor substrate by its corresponding insulating film;
an upper electrode provided on the upper surface of the semiconductor substrate; and
a lower electrode provided on a lower surface of the semiconductor substrate,
wherein
the diode region comprises:
an n-type bypass region disposed at the upper surface of the semiconductor substrate, being in direct contact with each insulating film, and connected to the upper electrode;
a p-type anode contact region disposed at the upper surface of the semiconductor substrate and connected to the upper electrode;
a p-type body region disposed below the bypass region and the anode contact region, being in direct contact with each insulating film below the bypass region, and having a p-type impurity concentration lower than the anode contact region;
an n-type drift region being in direct contact with each insulating film below the body region; and
an n-type cathode region disposed below the drift region, disposed at the lower surface of the semiconductor substrate, having an n-type impurity concentration higher than the drift region, and connected to the lower electrode,
wherein
a position of a lower end of the anode contact region is located below a position of a lowerend of the bypass region.

2. The semiconductor device of claim 1, Wherein the diode region further comprises:
an n-type barrier region disposed between the body region and the drift region, being in direct contact with each insulating film below the body region, and having an n-type impurity concentration higher than the drift region; and
a p-type lower body region disposed between the barrier region and the drift region, being in direct contact with each insulating film below the harrier region, and separating the harrier region and the drift region.

3. The semiconductor device of claim 2, wherein the diode region further comprises an n-type pillar region extending from the upper surface of the semiconductor substrate to the barrier region through the anode contact region and the body region.
